(19) United States
(12) Patent Application Publication
(10) Pub. No.: US 2025/0285928 A1
(43) Pub. Date: Sep. 11, 2025

(54) SEMICONDUCTOR PACKAGE AND METHOD OF MANUFACTURING THE SAME

(71) Applicant: Samsung Electronics Co., Ltd., Suwon-si (KR)

(72) Inventor: Sanghoon Lee, Suwon-si (KR)

(21) Appl. No.: 19/047,681

(22) Filed: Feb. 7, 2025

(30) Foreign Application Priority Data
Mar. 11, 2024 (KR) 10-2024-0033678

(51) Int. Cl. H01L 23/31; H01L 21/56; H01L 23/00; H01L 23/14; H01L 23/29; H01L 25/07; H10B 80/00

(52) U.S. Cl. CPC H01L 23/3135; H01L 21/56; H01L 24/08; H01L 24/09; H01L 25/071; H01L 23/147; H01L 23/291; H01L 2224/08145; H01L 2224/09181; H01L 2225/06517; H01L 2225/06541; H10B 80/00

(57) ABSTRACT

A semiconductor package includes a first die structure including a support substrate having a first surface and a second surface opposite to the first surface and having an opening that extends from the first surface to the second surface, a first semiconductor chip disposed in the opening, and a gap filling layer that fills a gap between a sidewall of the opening and the first semiconductor chip; and a second die structure stacked on the first die structure, the second die structure including a second semiconductor chip that is electrically connected to the first semiconductor chip. An outer side surface of the support substrate and an outer side surface of the second semiconductor chip are positioned on the same plane.

### PRIORITY STATEMENT

This application claims priority under 35 U.S.C. § 119 to Korean Patent Application No. 10-2024-0033678, filed on Mar. 11, 2024 in the Korean Intellectual Property Office (KIPO), the contents of which are herein incorporated by reference in their entirety.

### BACKGROUND

### 1. Field

The invention relates to a semiconductor package and a method of manufacturing the semiconductor package. More particularly, the invention relates to a semiconductor package including a plurality of stacked semiconductor chips and a method of manufacturing the same.

### 2. Description of the Related Art

In order to manufacture a semiconductor package including stacked semiconductor chips, a plurality of first semiconductor chips may be placed on a carrier substrate and a gap filling layer may be formed to fill spaces between the plurality of first semiconductor chips to form a reconstructed wafer, and then, the reconstructed wafer may be attached to a target wafer including second semiconductor chips provided therein by a wafer-to-wafer bonding process. However, in the reconstructed wafer, a step difference may occur between an upper surface of the first semiconductor chip and an upper surface of the gap filling layer, thereby generating voids during the wafer-to-wafer bonding process. For example, a bevel step difference may occur in an edge region of the reconstructed wafer, thereby causing voids in the bevel region during the wafer-to-wafer bonding process.

### SUMMARY

Aspects of the invention provide a semiconductor package having improved bonding quality. Aspects of the invention provide a method of manufacturing the semiconductor package.

According to example embodiments, a semiconductor package includes a first die structure including a support substrate having an opening therein, a first semiconductor chip disposed in the opening, and a gap filling layer that fills a gap between a sidewall of the opening and the first semiconductor chip. The semiconductor package further includes a second die structure stacked on the first die structure. The second die structure includes a second semiconductor chip that is electrically connected to the first semiconductor chip. The first semiconductor chip includes a first circuit substrate, a first front insulating layer formed on a first surface of the first circuit substrate and provided with first bonding pads, and a first backside insulating layer formed on a second surface opposite to the first surface of the first circuit substrate and provided with second bonding pads. The second semiconductor chip includes a second circuit substrate and a second front insulating layer formed on a first surface of the second circuit substrate and provided with third bonding pads. The second bonding pads are directly bonded to the third bonding pads respectively.

According to example embodiments, a semiconductor package includes a first die structure and a second die structure stacked on the first die structure. The first die structure includes a support substrate having a first surface and a second surface opposite to the first surface and having an opening that extends from the first surface to the second surface, a first semiconductor chip disposed in the opening, and a gap filling layer that fills a gap between a sidewall of the opening and the first semiconductor chip. The second die structure includes a second semiconductor chip that is electrically connected to the first semiconductor chip. An outer side surface of the support substrate and an outer side surface of the second semiconductor chip may be positioned on the same plane.

According to example embodiments, a semiconductor package includes a first semiconductor chip, a plurality of die structures sequentially stacked on the first semiconductor chip, and a second semiconductor chip stacked on an uppermost die structure of the plurality of die structures. Each of the plurality of die structures includes a support substrate having an opening therein, a third semiconductor chip disposed in the opening, and a gap filling layer that fills a gap between a sidewall of the opening and the third semiconductor chip. An outer side surface of the support substrate of the uppermost die structure and an outer side surface of the second semiconductor chip may be positioned on the same plane.

According to example embodiments, in a method of manufacturing a semiconductor package, a support substrate having a first surface and a second surface opposite the first surface is provided. A recess is formed in the support substrate to have a predetermined depth from the first surface. A first semiconductor chip is disposed within the recess. A gap filling layer is formed to fill a gap between an outer side surface of the first semiconductor chip and a sidewall of the recess. A portion of the support substrate is partially removed to expose the first semiconductor chip. The removed portion of the support substrate is adjacent to the second surface of the support substrate. A second semiconductor chip is bonded on the support substrate to be electrically connected to the first semiconductor chip.

In example embodiments, the disposing of the first semiconductor chip in the recess may include: providing the first semiconductor chip including: a first circuit substrate, a plurality of through electrodes penetrating the first circuit substrate, and a first front insulating layer formed on a first surface of the first circuit substrate and provided with first bonding pads electrically connected to the plurality of through electrodes, and disposing the first semiconductor chip in the recess such that the first front insulating layer faces the support substrate.

In example embodiments, the method may further include: forming a first backside insulating layer on a second surface of the first circuit substrate provided with second bonding pads electrically connected to the plurality of through electrodes, and the second surface of the first circuit substrate is opposite to the first surface of the first circuit substrate; and removing a portion of the first circuit substrate to expose end portions of the plurality of through electrodes, and the removed portion of the first circuit substrate being adjacent to the second surface of the first circuit substrate. The forming of the gap filling layer may include: forming the gap filling layer on the first surface of the support substrate to cover the first semiconductor chip, and removing an upper portion of the gap filling layer to expose the end portions of the plurality of through electrodes.

In example embodiments, the bonding of the second semiconductor chip on the support substrate may include: providing the second semiconductor chip including a second circuit substrate and a second front insulating layer formed on a first surface of the second circuit substrate and provided with third bonding pads; and bonding the second front insulating layer of the second semiconductor chip to the first backside insulating layer of the first semiconductor chip.

In example embodiments, the bonding of the second front insulating layer to the first backside insulating layer may include directly bonding the third bonding pads to the second bonding pads.

In example embodiments, the method may further include forming conductive bumps respectively on the first bonding pads of the first semiconductor chip exposed by the first front insulating layer.

In example embodiments, the gap filling layers may be formed of silicon oxide.

According to example embodiments, a semiconductor package may include a first die structure and a second die structure stacked on the first die structure. The first die structure may include a support substrate having a recess therein, a first semiconductor chip disposed in the recess, and a gap filling layer that fills a gap between a sidewall of the recess and the first semiconductor chip. The second die structure may include a second semiconductor chip electrically connected to the first semiconductor chip. The first semiconductor chip may include a first circuit substrate, a first front insulating layer formed on a first surface of the first circuit substrate and provided with first bonding pads, and a first backside insulating layer formed on a second surface opposite to the first surface of the first circuit substrate and provided with second bonding pads.

According to example embodiments, an outer side surface of the second semiconductor chip and an outer side surface of the support substrate may be positioned on the same plane. The first backside insulating layer of the first semiconductor chip may laterally extend along the second surface of the first circuit substrate to cover the gap filling layer. The first backside insulating layer of the first semiconductor chip may be directly bonded to the second front insulating layer of the second semiconductor chip. The second surface of the first circuit substrate of the first semiconductor chip and the second surface of the support substrate that includes silicon may be located on the same plane. The second surface of the first circuit substrate of the first semiconductor chip and the upper surface of the gap filling layer may be located on the same plane.

According to example embodiments, since no step difference occurs between a backside surface of the first circuit substrate of the first semiconductor chip and the upper surface of the gap filling layer, it may be possible to prevent voids from occurring during a wafer-to-wafer bonding process of the support substrate, in which the first semiconductor chip is formed, and the second semiconductor chip.

### BRIEF DESCRIPTION OF THE DRAWINGS

Example embodiments will be more clearly understood from the following detailed description taken in conjunction with the accompanying drawings. FIGS. 1 to 29 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is a plan view illustrating a lower die structure in FIG. 1.

FIGS. 4 to 19 are views illustrating a method of manufacturing a semiconductor package in accordance with example embodiments.

FIG. 20 is a cross-sectional view illustrating a semiconductor package in accordance with example embodiments.

FIG. 21 is a cross-sectional view illustrating an intermediate core die stack of the semiconductor package in FIG. 20.

FIGS. 22 to 28 are cross-sectional views illustrating a method of manufacturing a semiconductor package in accordance with example embodiments.

FIG. 29 is a cross-sectional view illustrating a semiconductor package in accordance with example embodiments.

### DETAILED DESCRIPTION OF EXAMPLE EMBODIMENTS

Hereinafter, example embodiments will be explained in detail with reference to the accompanying drawings.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Items described in the singular herein may be provided in plural, as can be seen, for example, in the drawings. Thus, the description of a single item that is provided in plural should be understood to be applicable to the remaining plurality of items unless context indicates otherwise.

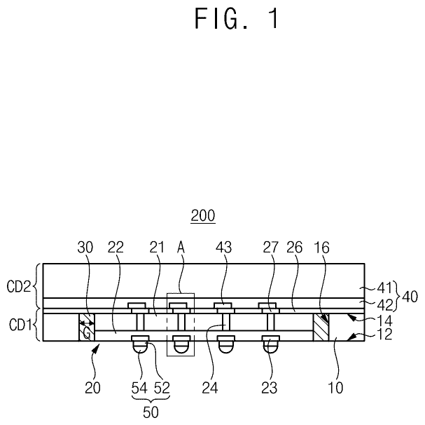

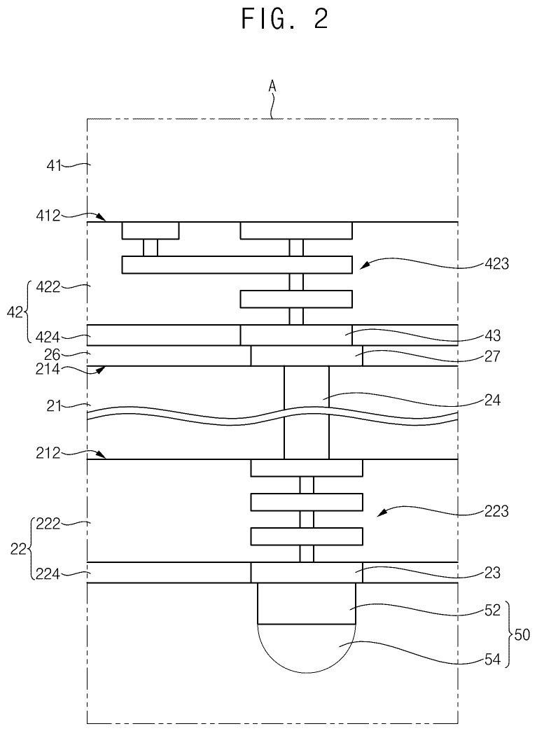

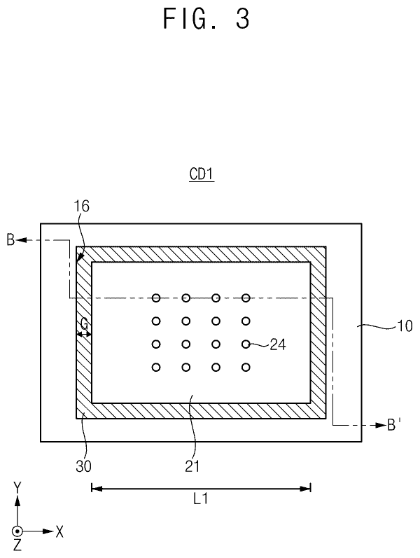

FIG. 1 is a cross-sectional view illustrating a semiconductor package in accordance with example embodiments. FIG. 2 is an enlarged cross-sectional view illustrating portion ‘A’ in FIG. 1. FIG. 3 is a plan view illustrating a lower die structure in FIG. 1. FIG. 1 is a cross-sectional view along the line B-B′ of FIG. 3.

Referring to FIGS. 1 to 3, a sub-package 200 may include a first die structure CD1 having a first semiconductor chip 20 and a second die structure CD2 stacked on the first die structure CD1 having a second semiconductor chip 40 that is bonded to the first semiconductor chip 20. Additionally, the sub-package 200 may further include conductive bumps 50 provided on an outer surface of the first semiconductor chip 20.

In example embodiments, the sub-package 200 may be a multi-chip package (MCP) including different types of semiconductor chips. For example, the sub-package 200 may be a chiplet package that includes a plurality of stacked chiplet dies. The stacked semiconductor chips may include the first semiconductor chip 20 as a first chiplet die and the second semiconductor chip 40 as a second chiplet die. For example, the first semiconductor chip 20 and the second semiconductor chip 40 may be small structural units of a semiconductor processor or IP block units that constitute a semiconductor processor. The first semiconductor chip 20 and the second semiconductor chip 40 may be stacked on each other to form a semiconductor device (e.g., a semiconductor processor).

As used herein, a semiconductor device may refer, for example, to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices. Semiconductor packages may include a package substrate, one or more semiconductor chips, and an encapsulant formed on the package substrate and covering the semiconductor chips.

The sub-package 200 may be provided as a logic chip including a logic circuit. The logic chip may be a controller that controls a memory chip. For example, the logic chip may be an ASIC serving as a host such as a CPU, GPU, or SOC, or serving as a processor chip such as an application processor AP.

In some embodiments, the sub-package 200 may include a memory chip such as DRAM, SRAM, etc. For example, the first and second semiconductor chips 20 and 40 may be a memory chip and a logic chip, respectively. The memory chip may be a cache memory chip. Alternatively, in other embodiments, both semiconductor chips 20 and 40 may be memory chips.

In this embodiment, the sub-package as a multi-chip package is illustrated as including two stacked semiconductor chips (also described as chiplet dies or dies) 20 and 40. However, the invention is not limited thereto, and for example, the sub-package may include 4, 8, 12, or 16 stacked semiconductor chips.

In example embodiments, the first die structure CD1 as a lower die structure may include a support substrate 10 having an opening 16 therein. The first die structure CD1 may further include a first semiconductor chip 20 disposed in the opening 16. A gap filling layer 30 may fill a gap G between an inner wall (also described as a sidewall) of the opening 16 and a first semiconductor chip 20. The second die structure CD2 as an upper die structure may be stacked on the first die structure CD1. The second die structure CD2 may include a second semiconductor chip 40 electrically and/or directly connected to the first semiconductor chip 20. The first and second die structures CD1 and CD2 may be subject to certain processes to form a final sub-package. Accordingly, the die structures may be described as intermediate packages.

It will be understood that when an element is referred to as being “connected” or “coupled” to or “bonded” to or “on” another element, it can be directly connected or coupled to or on the other element or intervening elements may be present. In contrast, when an element is referred to as being “directly connected” or “directly coupled” to or “directly bonded” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

As illustrated in FIG. 1, the support substrate 10 may have a first surface (e.g., a lower surface) 12 and a second surface (e.g., an upper surface) 14 opposite to the first surface 12. The support substrate 10 may have the opening 16 in a center region thereof in a plan view (as viewed from the vertical direction Z). The opening 16 may extend from the first surface 12 to the second surface 14 of the support substrate 10. For example, the support substrate 10 may be or include at least one of a silicon substrate, a silicon substrate, a non-metallic plate, a metallic plate, etc. A thickness of the support substrate 10 may be within a range of 10 μm to 50 μm.

The first semiconductor chip 20 may include a first substrate 21 and a first front insulating layer 22, a plurality of first bonding pads 23, a plurality of through electrodes 24, a first backside insulating layer 26 and a plurality of second bonding pads 27.

The first substrate 21 may have a first surface 212 and a second surface 214 opposite the first surface 212. Circuit patterns may be formed on or provided with the first surface 212 of the first substrate 21. The first surface 212 may be an active surface, and the second surface may be an inactive surface. For example, the first substrate 21 may be a single crystal silicon substrate. The circuit patterns may include transistors, capacitors, diodes, etc. The circuit patterns may constitute circuit elements (e.g., a logic gate, such as a NAND, OR, XOR, NOT (an inverter), NAND, NOR, or an XNOR gate). For example, the first semiconductor chip 20 may be a semiconductor device in which a plurality of circuit elements are formed.

As illustrated in FIG. 2, the first front insulating layer 22 may be provided on the first surface 212 of the first substrate 21. For example, the first surface 212 may be described as an active surface of the first substrate 21. The first front insulating layer 22 may include a plurality of insulating layers 222 and 224. A plurality of first metal wiring layers 223 may be provided in the insulating layers. In addition, the first bonding pads 23 may be provided in an outermost insulating layer (e.g., a first passivation layer) 224 of the first front insulating layer 22.

For example, the first front insulating layer 22 may surround the plurality of first metal wiring layers 223. For example, the plurality of first metal wiring layers 223 may be a metal wiring structure having the plurality of wirings vertically stacked in the insulating layer 222. The first bonding pad 23 may be formed on an uppermost wiring among the plurality of wirings 223. For example, the wirings may include (or be formed of) aluminum (Al), copper (Cu), tin (Sn), nickel (Ni), gold (Au), platinum (Pt), or an alloy thereof.

Throughout the specification, when a component is described as “including” (or any form of the word “include”) a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

The first passivation layer 224 may be formed on the first metal wiring layer 223 and may expose at least a portion of the first bonding pad 23. The first passivation layer 224 may be a composite layer including a plurality of stacked insulating layers. For example, the first passivation layer 224 may include an oxide layer, silicon nitride or silicon carbonitride. The first passivation layer 224 may have a single-layer or multi-layer structure.

The first bonding pad 23 may be provided in the first passivation layer 224. The first bonding pad 23 may be exposed through an opening of the first passivation layer 224 or beyond an outer surface of the first passivation layer 224. Although not illustrated in the figures, an additional insulation layer may be provided on the first surface 212 of the first substrate 21 to cover the circuit patterns.

The through electrode 24 such as a through silicon via (TSV) may vertically penetrate the first substrate 21, and may extend from the first surface 212 to the second surface 214. Although not illustrated in the figures, in an alternative embodiment, the through electrode 24 may extend from either the first surface 212 or the second surface 214 to a predetermined depth, and the through electrode 24 may not entirely vertically penetrate the first substrate 21. The through electrode 24 may contact the lowest wiring of the metal wiring structure. Accordingly, the through electrode 24 may be electrically connected to the first bonding pad 23 through the wirings 223. In another alternative embodiment, the through electrode 24 may entirely vertically penetrate the insulating layer 222, thereby the through electrode 24 being in contact with the first bonding pad 23.

The first backside insulating layer 26 may be formed on the second surface 214 of the first substrate 21. The second surface 214 may be described as a backside surface of the first substrate 21. The second bonding pad 27 may be provided in the first backside insulating layer 26. For example, the second bonding pad 27 may be disposed on an exposed surface of the through electrode 24. The first backside insulating layer 26 may be formed of or include at least one of silicon oxide, carbon-doped silicon oxide, silicon carbonitride (SiCN), etc. The first bonding pads 23 and the second bonding pad 27 may be electrically connected to each other by the through electrode 24.

As illustrated in FIG. 3, the gap filling layer 30 may fill a gap G between an outer side surface of the first semiconductor chip 20 and a sidewall of the opening 16 of the support substrate 10. The gap filling layer 30 may surround the first semiconductor chip 20 in a plan view. For example, the gap filling layer 30 may be formed of or include silicon oxide such as TEOS. The gap filling layer may include an inorganic dielectric layer or an organic dielectric layer. The inorganic dielectric layer may be formed of or include at least one of silicon oxide, silicon oxynitride, phosphosilicate glass (PSG), boro-phosphosilicate glass (BPSG), etc. The organic dielectric layer may include a polymer or the like. The gap filling layer may include or be an insulating material having a coefficient of thermal expansion smaller than the support substrate 10. The gap filling layer may have a hardness lower than the support substrate 10.

The first front insulating layer 22 of the first semiconductor chip 20 may be exposed by the gap filling layer 30. The gap filling layer 30 may fill a gap between an outer side surface of the first front insulating layer 22 and a sidewall of the opening 16 of the support substrate 10. The gap filling layer 30 may surround the first front insulating layer 22 in a plan view. An outer surface (i.e., a lower surface) of the first front insulating layer 22 and a lower surface of the gap filling layer 30 may be located on the same plane. The lower surface of the gap filling layer 30 and the first surface 12 of the support substrate 10 may be located on the same plane.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical acceptable variations that may occur resulting from conventional manufacturing processes or within typical acceptable variations that may occur resulting from a noise component or a measurement error when measured. The term “substantially” may be used herein to emphasize this meaning, unless the context or other statements indicate otherwise.

The second surface 214 of the first substrate 21 of the first semiconductor chip 20 may be coplanar with the second surface 14 of the support substrate 10. The second surface 214 of the first substrate 21 and the upper surface of the gap filling layer 30 may be located on the same plane. The upper surface of the gap filling layer 30 and the second surface 14 of the support substrate 10 may be located on the same plane.

The first backside insulating layer 26 of the first semiconductor chip 20 may extend laterally from the second surface 214 of the first substrate 21 to cover the gap filling layer 30 and the second surface 14 of the support substrate 10.

In example embodiments, the second semiconductor chip 40 may be stacked on the first semiconductor chip 20 and the support substrate 10. The second semiconductor chip 40 may include a second substrate 41, a second front insulating layer 42, and a plurality of third bonding pads 43.

Circuit patterns may be formed on or provided with a first surface 412 of the second substrate 41, that is an active surface. For example, the second substrate 41 may be a single crystal silicon substrate. The circuit patterns may include transistors, capacitors, diodes, etc. The circuit patterns may constitute circuit elements. The second semiconductor chip 40 may be a semiconductor device in which a plurality of circuit elements are formed.

The second front insulating layer 42 may be provided on the first surface 412 of the second substrate 41, that is the active surface. The second front insulating layer 42 may include a plurality of insulating layers 422 and 424. A plurality of second metal wiring layers 423 may be provided in a first passivation layer 422. In addition, the third bonding pads 43 may be provided in an outermost insulating layer (e.g., a third passivation layer) 424 of the second front insulating layer 42.

For example, the second front insulating layer 42 may surround the plurality of the second metal wiring layers 423. For example, the plurality of second metal wiring layers 423 may be a metal wiring structure including a plurality of wirings vertically stacked in the insulating layer 422. The third bonding pad 43 may be formed on an uppermost wiring among the plurality of wirings 423. For example, the wirings may include aluminum (Al), copper (Cu), tin (Sn), nickel (Ni), gold (Au), platinum (Pt), or an alloy thereof.

The third passivation layer 424 may be formed on the plurality of second metal wiring layers 423 and may expose at least a portion of the third bonding pad 43. The third passivation layer 424 may be a composite layer including a plurality of stacked insulating layers. For example, the third passivation layer 424 may include or be formed of silicon oxide, silicon nitride, or silicon carbonitride. The third passivation layer 424 may have a single-layer or multi-layer structure.

The third bonding pad 43 may be provided in the third passivation layer 424. The third bonding pad 43 may be exposed through an opening of the third passivation layer 424 or beyond an outer surface of the third passivation layer 424.

As illustrated in FIG. 2, the first semiconductor chip 20 and the second semiconductor chip 40 may be bonded to each other by hybrid bonding. The front surface (e.g., a first surface) 412 of the second substrate (e.g., second circuit substrate) 41 of the second semiconductor chip 40 may face the backside surface 214 (e.g., a second surface) of the first substrate (also described first circuit substrate) 21 of the first semiconductor chip 20. The second front insulating layer 42 of the second semiconductor chip 40 and the first backside insulating layer 26 of the first semiconductor chip 20 may be directly bonded to each other. In addition, the second bonding pad 27 of the first semiconductor chip 20 and the third bonding pad 43 of the second semiconductor chip 40 may be bonded to each other by Cu—Cu bonding. For example, the second bonding pad 27 of the first semiconductor chip 20 and the third bonding pad 43 of the second semiconductor chip 40 may be directly bonded to each other.

The first backside insulating layer 26 of the first semiconductor chip 20 and the second front insulating layer 42 of the second semiconductor chip 40 may be directly bonded to each other. The first backside insulating layer 26 and the second front insulating layer 42 may be formed of a material providing excellent bonding strength, thereby contacting each other to form a bonding structure. The first backside insulating layer 26 and the second front insulating layer 42 may be bonded to each other by a high-temperature annealing process while in contact with each other, thereby accomplishing covalent bonding having a relatively strong bonding strength.

In example embodiments, an outer side surface of the second semiconductor chip 40 and an outer side surface of the support substrate 10 may be located on the same plane. In a plan view (as viewed from the vertical direction Z), the first semiconductor chip 20 may have a first size, and the second semiconductor chip 40 may have a second size that is greater than the first size. The first semiconductor chip 20 may have a first width (e.g., a first length) L1, and the second semiconductor chip 40 may have a second width (e.g., a second length) greater than the first width. The first semiconductor chip 20 may be disposed on a center region of the second semiconductor chip 40 in a plan view (as viewed from the vertical direction Z).

In example embodiments, the support substrate 10 may have a first coefficient of thermal expansion, and the gap filling layer 30 may have a second coefficient of thermal expansion that is greater than the first coefficient of thermal expansion. Since the support substrate 10 containing silicon has a denser composition than the gap filling layer 30, the support substrate 10 may have excellent mechanical strength and thermal resistance characteristics to temperature changes (or temperature hysteresis) compared to the gap filling layer 30. When viewed in a plan view, an area ratio occupied by the support substrate 10 to the total area of the first die structure CD may be within a range of 5% to 30%.

In example embodiments, the conductive bumps 50 may be disposed on the first bonding pads 23 on the first front insulating layer 22 of the first semiconductor chip 20, respectively. For example, each of the conductive bumps 50 may include a pillar bump 52 on the first bonding pad 23 and a solder bump 54 on the pillar bump 52. For example, the pillar bump may include copper (Cu), aluminum (Al), tin (Sn), nickel (Ni), gold (Au), platinum (Pt), or an alloy thereof. The solder bump may include solder. The sub-package 200 may be mounted on a substrate such as a package substrate, an interposer, or a redistribution wiring layer via the conductive bumps 50 to form a semiconductor package.

As mentioned above, the sub-package 200 may include the first die structure CD1 and the second die structure CD2 stacked on the first die structure CD1. The first die structure CD1 may include the support substrate 10 having the opening 16 therein, the first semiconductor chip 20 disposed in the opening 16, and the gap filling layer 30 that fills the gap G between the sidewall of the opening 16 and the first semiconductor chip 20. The second die structure CD2 may include the second semiconductor chip 40 that is electrically connected to the first semiconductor chip 20.

The outer side surface of the second semiconductor chip 40 and the outer side surface of the support substrate 10 may be located on the same plane. The first backside insulating layer 26 of the first semiconductor chip 20 may extend laterally from the second surface 214 of the first substrate 21 to cover the gap filling layer 30 and the second surface of the support substrate 10. The first backside insulating layer 26 of the first semiconductor chip 20 and the second front insulating layer 42 of the second semiconductor chip 40 may be directly bonded to each other.

The second surface 214 of the first substrate 21 of the first semiconductor chip 20 and the second surface 14 of the support substrate 10 that includes silicon may be located on the same plane. The second surface 214 of the first substrate 21 of the first semiconductor chip 20 and the upper surface of the gap filling layer 30 may be located on the same plane. The upper surface of the gap filling layer 30 and the second surface 14 of the support substrate 10 may be located on the same plane. Accordingly, since no step difference occurs between the backside surface of the first substrate 21 of the first semiconductor chip 20 and the upper surface of the gap filling layer 30, it may be possible to prevent voids from occurring during a bonding process of the wafers in which the first semiconductor chip 20 and the second semiconductor chip 40 are formed, respectively.

Hereinafter, a method of manufacturing the semiconductor package of FIG. 1 will be described.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

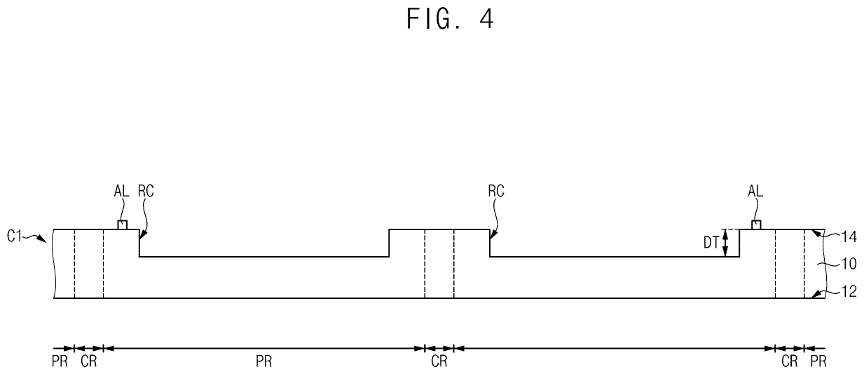

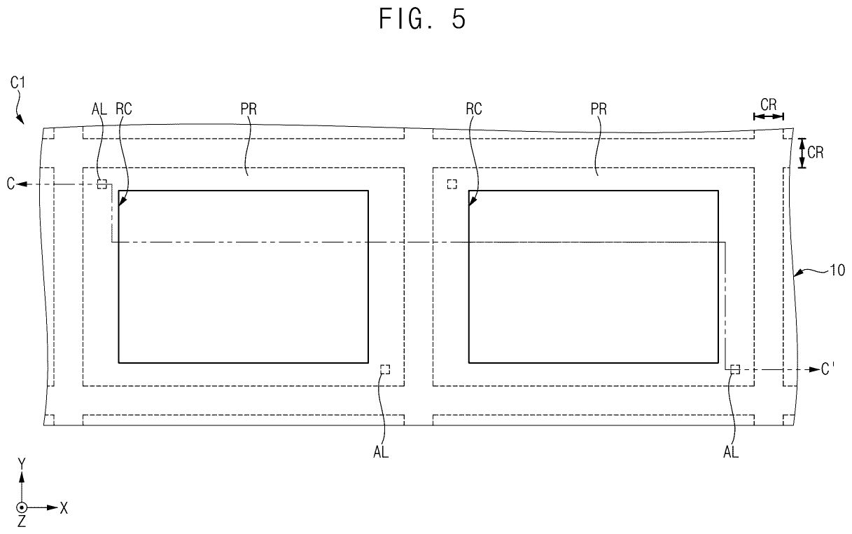

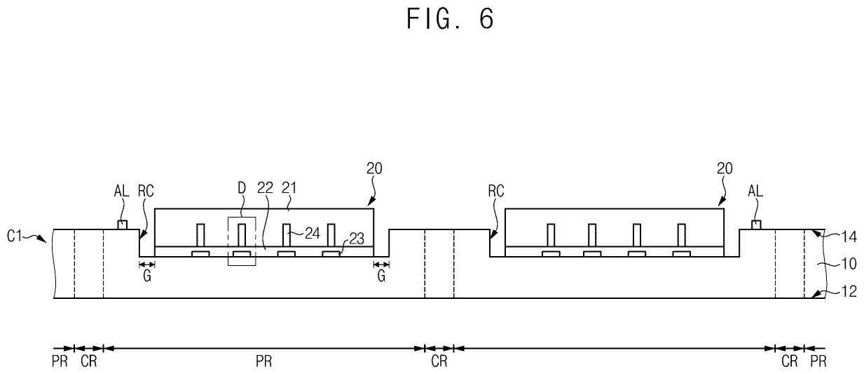

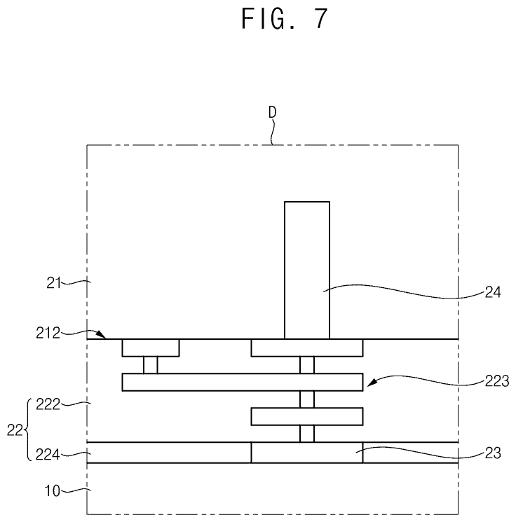

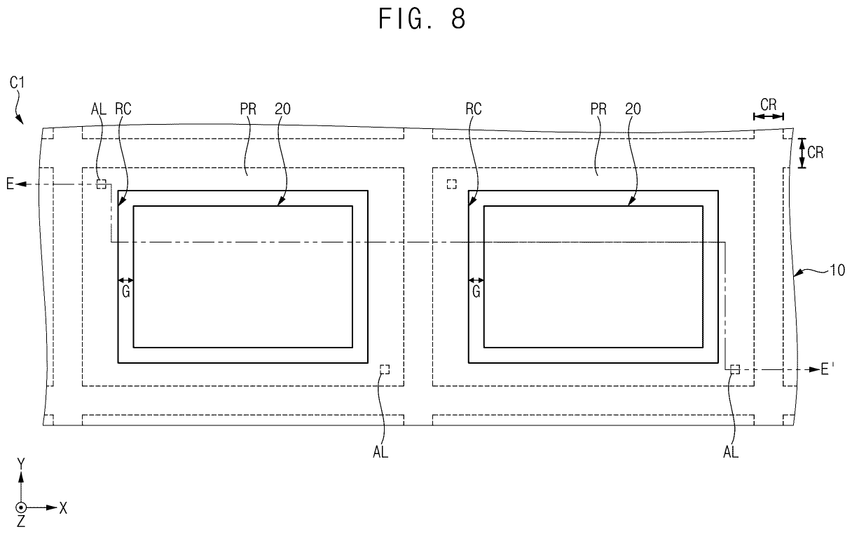

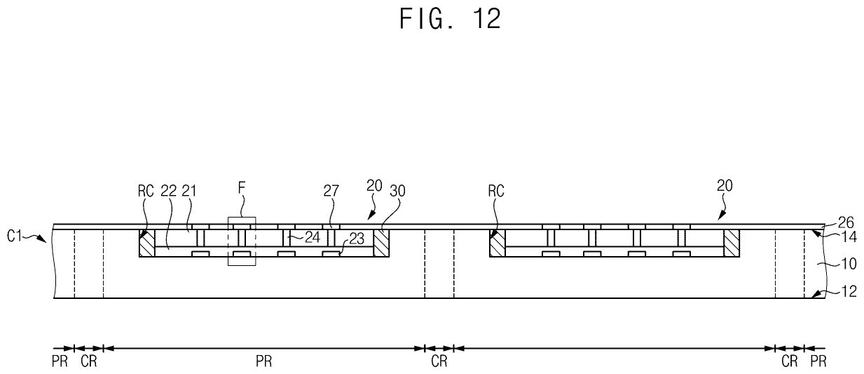

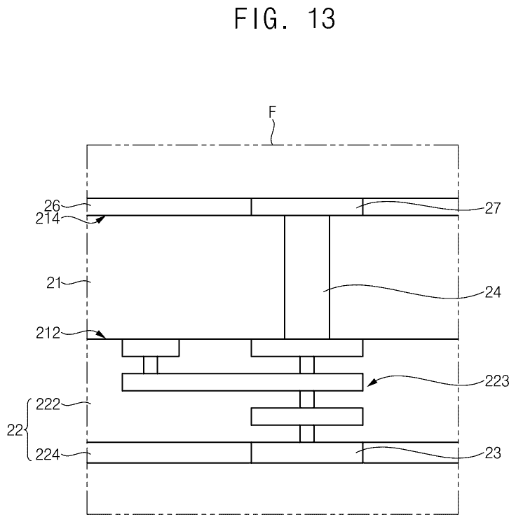

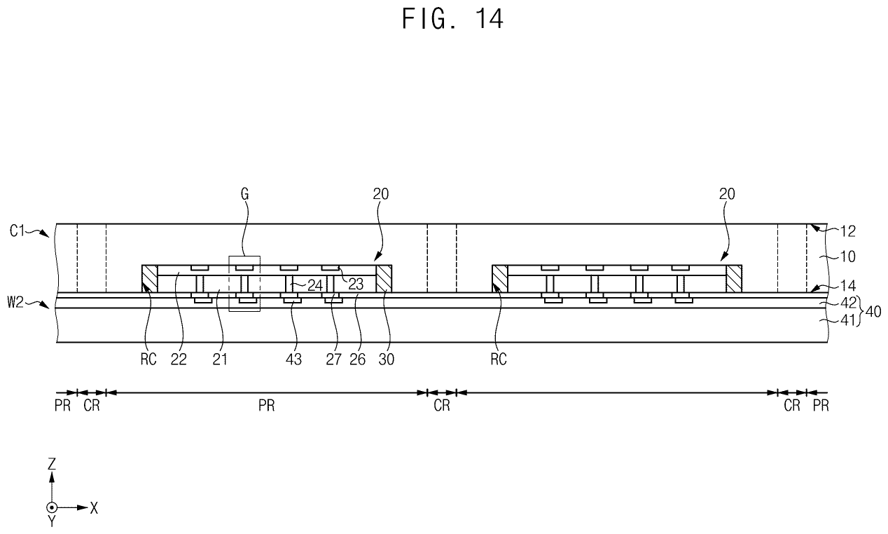

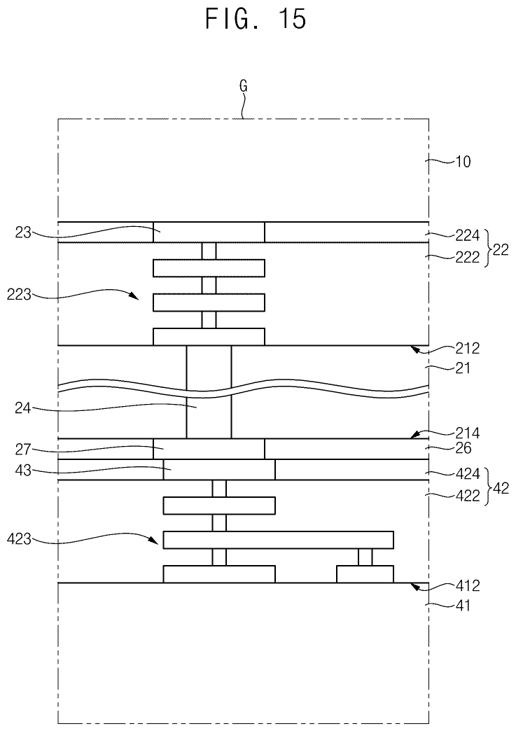

FIGS. 4 to 19 are views illustrating a method of manufacturing a sub-package in accordance with example embodiments. FIGS. 4, 6, 9 to 12, 14, and 16 to 19 are cross-sectional views illustrating a method of manufacturing a sub-package in accordance with example embodiments. FIG. 7 is an enlarged cross-sectional view illustrating portion ‘D’ in FIG. 6. FIG. 13 is an enlarged cross-sectional view illustrating portion ‘F’ in FIG. 12. FIG. 15 is an enlarged cross-sectional view illustrating portion ‘G’ in FIG. 14. FIG. 5 is a plan view of FIG. 4. FIG. 4 is a cross-sectional view taken along the line C-C′ in FIG. 5. FIG. 8 is a plan view of FIG. 6. FIG. 6 is a cross-sectional view taken along the line E-E′ in FIG. 8.

Referring to FIGS. 4 and 5, a carrier substrate C1 including a recess RC formed therein may be prepared. In example embodiments, the carrier substrate C1 may be provided as a support frame on which a first semiconductor chip (e.g., lower dies) is placed in the recess RC.

As described later, a gap filling layer may be formed to fill the recess, and the first semiconductor chip may be bonded to a second semiconductor chip of a target substrate (e.g., the second wafer W2 in FIG. 14) by using a substrate-to-substrate bonding. On the target substrate, a plurality of the second semiconductor chips 40 (shown in FIG. 1) may be formed.

The carrier substrate C1 and the target substrate have the same shape as each other in a plan view (as viewed from the vertical direction Z). For example, the carrier substrate C1 and the target substrate may have a shape of a wafer or a panel. For example, the carrier substrate C1 may be or include at least one of a silicon substrate, a silicon substrate, a non-metallic plate, a metallic plate, etc.

The carrier substrate C1 may be or include a silicon substrate 10 that has a first surface 12 and a second surface 14 opposite to the first surface 12. The carrier substrate C1 may include a package region PR on which the first semiconductor chip is mounted and a cutting region CR surrounding the package region PR. As will be described later, the carrier substrate C1 may be cut along the cutting region CR to form a plurality of individual support substrates. The cutting region CR may surround the first semiconductor chip.

As illustrated in FIGS. 4 and 5, alignment key patterns AL may be formed on the second surface 14 of the carrier substrate C1. For example, an oxide layer may be formed on the second surface 14 of the silicon substrate 10, and a patterning process and a plating process may be performed on the oxide layer to form the alignment key patterns AL. The alignment key patterns AL may include a metal material such as aluminum or copper. The alignment key patterns AL may be formed in a peripheral region of the package region PR or in the cutting region CR. As described later, a process of attaching the first semiconductor chip may be performed using the alignment key patterns AL.

The recess RC may be formed in the second surface 14 of the carrier substrate C1. The recess RC may accommodate the first semiconductor chip in a subsequent process step. The recesses RC may be formed in the package regions PR of the carrier substrate C1. For each of the package regions PR of the carrier substrate C1, at least one of the alignment key patterns AL may be used during the attaching process. The recess RC may be formed by a plasma etching process. Alternatively, the recess RC may be formed by a laser drilling process, a wet etching process, etc.

The recess RC may be a region in which the first semiconductor chip is disposed. The predetermined depth DT of the recess RC may be within a range of 10 μm to 50 μm. The recess RC may have an area greater than an area of the first semiconductor chip in a plan view (as viewed from the vertical direction Z). The recess RC may have a predetermined depth DT from the second surface 14 of the silicon substrate 10. For example, the area of the recess RC may be within a range of 105% to 115% of the area of the first semiconductor chip in a plan view (as viewed from the vertical direction Z). The area and depth of the recess RC may be determined in consideration of the area and thickness of the first semiconductor chip.

In some embodiments, the alignment key patterns AL may be formed within the recess RC. In this case, an oxide layer as a mold pattern layer may be formed on a bottom surface of the recess RC of the silicon substrate 10, and a patterning process and a plating process may be formed on the mold pattern layer to form the alignment key patterns AL.

Referring to FIGS. 6 to 8, a first semiconductor chip 20 may be disposed in the recess RC of the silicon substrate 10.

In example embodiments, a plurality of first semiconductor chips 20 may be provided. For example, the plurality of first semiconductor chips 20 may be individualized from a wafer by a sawing process. The plurality of first semiconductor chips 20 may be placed in the recesses RC of the silicon substrate 10. A front surface of the first semiconductor chip 20 may be stacked to face the silicon substrate 10. An upper portion of the first semiconductor chip 20 may protrude from the recess RC beyond the second surface 14 of the silicon substrate 10. The first semiconductor chip 20 may be a first chiplet die (e.g., a lower chiplet die). The first semiconductor chip 20 may be a small structural unit of a semiconductor processor or IP block units that constitute a semiconductor processor. The first semiconductor chip 20 and the second semiconductor chip 40 may be stacked on each other to form a semiconductor device (e.g., a semiconductor processor).

As illustrated in FIG. 7, the first semiconductor chip 20 may include a first substrate 21 and a first front insulating layer 22 provided with first bonding pads 23. Additionally, the first semiconductor chip 20 may further include a plurality of through electrodes 24 that are provided in the first substrate 21 and are electrically connected to the first bonding pads 23.

The first substrate 21 may have a first surface 212 and a second surface 214 opposite the first surface 212. Circuit patterns may be formed on the first surface 212 of the first substrate 21. For example, the first substrate 21 may include silicon, germanium, silicon-germanium, or III-V compounds (e.g., GaP, GaAs, GaSb, etc.). In some embodiments, the first substrate 21 may be a silicon-on-insulator (SOI) substrate, or a germanium-on-insulator (GOI) substrate.

The circuit patterns may include transistors, capacitors, diodes, etc. The circuit patterns may constitute circuit elements. Accordingly, the first semiconductor chip may be a semiconductor device in which a plurality of circuit elements are formed. The circuit patterns may be formed by performing a wafer fabrication process (which may be a Front End of Line (FEOL) process) on the first surface 212 of the first substrate 21. A surface of the first substrate, on which the FEOL process is performed, may be described as a front surface of the first substrate. A surface opposite to the front surface may be referred to as a backside surface.

The first front insulating layer 22 as an insulation layer may be formed on the first surface (front surface) 212 of the first substrate. The first front insulating layer 22 may include a plurality of insulating layers 222 and 224. A plurality of first metal wiring layers 223 may be provided in the insulating layers. In addition, the first bonding pads 23 may be provided in an outermost insulating layer (e.g., a first passivation layer) 224 of the first front insulating layer 22.

For example, the first front insulating layer 22 may surround the plurality of first metal wiring layer 223 and a first passivation layer 224. For example, the plurality of first metal wiring layer 223 may be a metal wiring structure having the plurality of wirings vertically stacked in the insulating layer 222. The first bonding pad 23 may be formed on an uppermost wiring among the plurality of wirings 223. For example, the wirings may include (or be formed of) aluminum (Al), copper (Cu), tin (Sn), nickel (Ni), gold (Au), platinum (Pt), or an alloy thereof.

The first passivation layer 224 may be formed on the first metal wiring layer 223 and may expose at least a portion of the first bonding pad 23. The first passivation layer 224 may be a composite layer including a plurality of stacked insulating layers. For example, the first passivation layer 224 may include an oxide layer, silicon nitride or silicon carbonitride. The first passivation layer 224 may have a single-layer or multi-layer structure.

The first bonding pad 23 may be provided in the first passivation layer 224. The first bonding pad 23 may be exposed through an opening of the first passivation layer 224 or beyond an outer surface of the first passivation layer 224. Although not illustrated in the figures, an additional insulation interlayer may be provided on the first surface 212 of the first substrate 21 to cover the circuit patterns.

The insulation layer 22 may be formed of, for example, silicon oxide or a low dielectric material. The first metal wiring layer 223 may be electrically connected to the circuit patterns. Accordingly, the circuit pattern may be electrically connected to the first bonding pad 23 by the first metal wiring layer 223.

The through electrode 24 such as through silicon via (TSV) may extend from the first surface 212 of the first substrate 21 to a predetermined depth. The through electrode 24 may contact the first metal wiring layer 223. Accordingly, the through electrode 24 may be electrically connected to the first bonding pad 23 through the first metal wiring layer 223. In some embodiments, the substrate 21 may further include an insulating layer and the through electrode 24 may vertically penetrate the insulation interlayer.

A liner layer (not illustrated in the drawings) may be provided on an outer surface of the through electrode 24. The liner layer may include or be formed of silicon oxide or carbon-doped silicon oxide. The liner layer may electrically insulate the through electrode 24 from the first substrate 21 and the first metal wiring layer 223.

The through electrode 24 and the first bonding pad 23 may include the same metal. For example, the metal may include copper (Cu). However, the invention is not limited thereto, and the metal may further include a material (e.g., gold (Au)) that can be combined by interdiffusion of metals (e.g., interdiffusion between Au and Cu) by a high-temperature annealing process.

As illustrated in FIG. 8, an outer side surface of the first semiconductor chip 20 may be spaced apart from a sidewall of the recess RC. A gap G between the outer side surface of the first semiconductor chip 20 and the sidewall of the recess RC may be within a range of 5 μm to 10 μm.

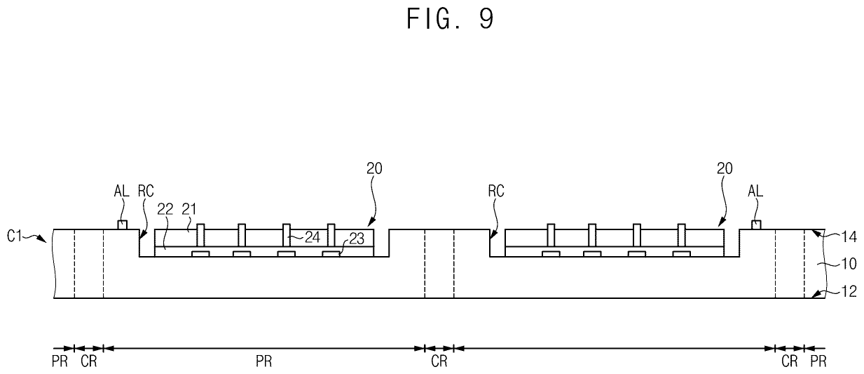

Referring to FIG. 9, the second surface 214 of the first substrate 21 may be partially removed to expose an end portion of the through electrode 24.

In example embodiments, a grinding process such as a back lap process may be performed to partially remove a portion of the first substrate 21, which is adjacent to the second surface 214 of the first substrate 21. In the back lap process, the entire backside surface of the first substrate 21 may be subject to the grinding process (i.e., the back lap process).

Subsequently, a silicon recess process such as an etching process may be performed to further remove an additional portion of the first substrate 21, which is adjacent to the second surface 214 of the first substrate 21 and to expose end portions of the through electrodes 24. Accordingly, a thickness of the first substrate 21 may be reduced to a desired thickness. For example, the thickness of the first substrate 21 may be in a range of from about 20 μm to about 100 μm. As a result of the silicon recess process, the second surface 214 of the first substrate 21 may be coplanar or higher than the second surface 14 of the silicon substrate 10. The silicon recess process may selectively etch only silicon in the backside surface of the first substrate 21 without removing the silicon in the second surface 14 of the silicon substrate 10. Accordingly, the end portions of the through electrodes 24 may protrude beyond the second surface 214 of the first substrate 21. The etching process may be an isotropic dry etching process. The etching process may include a plasma etching process. The plasma etching process may be performed using inductively coupled plasma, capacitively coupled plasma, microwave plasma, etc. For example, the protruding end portions of the through electrodes 24 may have the same heights from the second surface 214 of the first substrate 21 as each other.

In an alternative embodiment, the back lap process may be performed to expose the end portions of the through electrodes 24, and optionally the silicon recess process may not be performed. In another alternative embodiment, the back lap process may be performed to expose the end portions of the through electrodes 24 such that the end portions protrudes beyond the second surface 214 of the first substrate 21, and optionally the silicon recess process may not be performed.

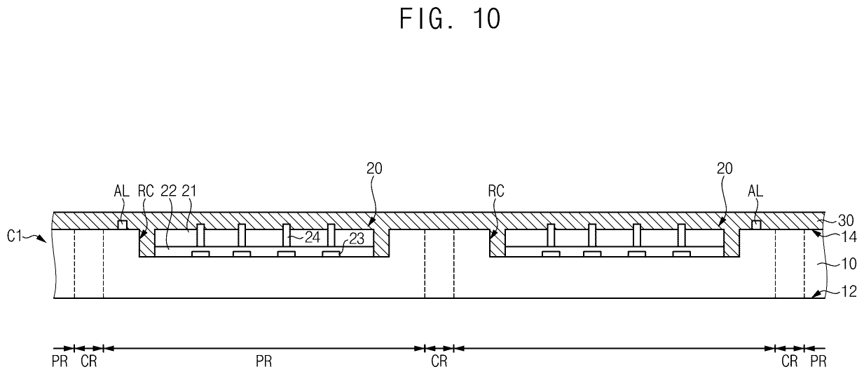

Referring to FIG. 10, a gap filling layer 30 may be formed on the second surface 14 of the carrier substrate C1 to cover the first semiconductor chip 20.

In example embodiments, the gap filling layer 30 may be formed to fill the gap between the outer side surface of the first semiconductor chip 20 and the sidewall of the recess RC. The gap filling layer 30 may be formed to cover the second surface 14 of the silicon substrate 10. The gap filling layer 30 may be formed to fill the gap between the protruding end portions of the through electrodes 24 on the second surface 214 of the first substrate 21. The gap filling layer 30 may be formed of or include silicon oxide such as TEOS.

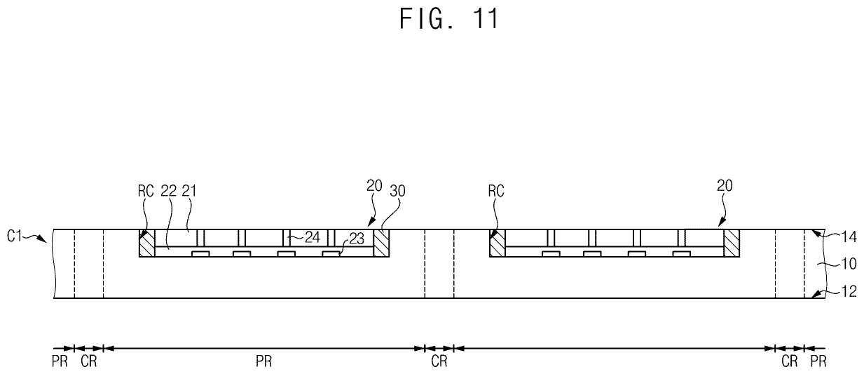

Referring to FIGS. 11 to 13, a first backside insulating layer 26 provided with second bonding pads 27 in an outer surface thereof may be formed on the second surface 214 of the first substrate 21.

As illustrated in FIG. 11, an upper portion of the gap filling layer 30 may be removed to expose the end portions of the through electrodes 24. At this time, the second surface 214 of the first substrate 21 may be exposed as well. For example, the second surface 214 of the first substrate 21 may be exposed simultaneously with the end portions of the through electrodes 24.

In example embodiments, a chemical mechanical polishing (CMP) process may be performed to remove the upper portion of the gap filling layer 30 to expose the end portions of the through electrodes 24. For example, during the CMP process, the second surface 14 of the silicon substrate 10 (e.g., a passivation layer on the second surface 14) may be utilized to detect a polishing end point. Through the CMP process, the end portions of the through electrodes 24 as well as the portion of the gap filling layer covering the end portions may be removed to expose the second surface 214 of the first substrate 21 (e.g., the passivation layer on the second surface 14). The second surface 14 of the silicon substrate 10 and the second surface 214 of the first substrate 21 may be positioned on the same plane. The second surface 14 of the silicon substrate 10 and an upper surface of the gap filling layer 30 may be positioned on the same plane. The upper surface of the gap filling layer 30 and the second surface 214 of the first substrate 21 may be positioned on the same plane. In some embodiments of the invention, during the CMP process, an upper portion of the second surface 214 of the first substrate 21 may be removed as well.

Accordingly, since no step difference is generated between the backside surface of the first substrate 21 of the first semiconductor chip 20 and the upper surface of the gap filling layer 30, voids may be prevented from occurring during a subsequent wafer-to-wafer bonding process of the first semiconductor chip 20 and the second semiconductor chip. For example, since no bevel step difference occurs between the second surface 14 of the silicon substrate 10 and the backside surface of the first substrate 21 of the first semiconductor chip 20 at an edge region of the carrier substrate C1, voids may be prevented from occurring in the bevel region during the subsequent wafer-to-wafer bonding process of the first semiconductor chip 20 and the second semiconductor chip.

As illustrated in FIGS. 12 and 13, the first backside insulating layer 26 as a second passivation layer may be formed on the second surface 214 of the first substrate 21, and the second bonding pad 27 that is electrically connected to the through electrode 24 may be formed in the first backside insulating layer 26.

For example, the first backside insulating layer 26 may be formed of or include at least one of silicon oxide, carbon-doped silicon oxide, silicon carbonitride (SiCN), etc. After the first backside insulating layer 26 is formed on the second surface 214 of the first substrate 21, a through hole may be formed in the first backside insulating layer 26 to expose the through electrode 24 and a plating process may be performed to form the second bonding pad 27. The second bonding pad 27 may be disposed on the exposed upper surface of the through electrode 24. Accordingly, the first bonding pads 23 and the second bonding pads 27 may be electrically connected to each other by the through electrode 24.

Referring to FIGS. 14 and 15, a second wafer W2, in which a second semiconductor chip 40 is formed, may be provided. Subsequently, the carrier substrate C1 of FIG. 12, in which the first semiconductor chip 20, is formed may be attached on the second wafer W2, for example, by a wafer-to-wafer hybrid bonding process.

In example embodiments, the structure of FIG. 12 may be turned over, and the carrier substrate C1 may be bonded onto the second wafer W2. Accordingly, a backside surface of the first semiconductor chip 20 may face a front surface of the second semiconductor chip 40 of the second wafer W2.

When the carrier substrate C1 and the second wafer W2 are bonded to each other in a wafer-to-wafer bonding manner, a thermal compression process may be performed. For example, the stacked wafers of the carrier substrate C1 and the second wafer W2 may be subject to the thermal compression process such that the first semiconductor chip 20 and the second semiconductor chip 40 are bonded to each other in a manner of hybrid bonding. For example, the second bonding pad 27 may be directly bonded to the third bonding pads 43. Additionally, the front surface of the second semiconductor chip 40 (i.e., a second front insulating layer 42) may be directly bonded to the backside surface of the first semiconductor chip 20 (i.e., the backside insulating layer 26).

When the carrier substrate C1 and the second wafer W2 are bonded to each other by wafer-to-wafer bonding, there is no step difference between the backside surface of the first substrate 21 of the first semiconductor chip 20 and the upper surface of the gap filling layer 30. Accordingly, it may be possible to prevent voids from occurring between the first backside insulating layer 26 of the first semiconductor chip 20 and the second front insulating layer 42 of the second semiconductor chip 40. For example, when the carrier substrate C1 and the second wafer W2 are bonded to each other by wafer-to-wafer bonding, there is no bevel step difference between the second surface 14 of the silicon substrate 10 and the backside surface of the first substrate 21 of the first semiconductor chip 20 at the edge region of the carrier substrate C1. Accordingly, it may be possible to prevent a void from occurring between the edge region of the carrier substrate C1 and an edge region of the second wafer W2.

As illustrated in FIG. 15, the second semiconductor chip 40 may include the second substrate 41 and the second front insulating layer 42 provided with third bonding pads 43 in an outer surface thereof. The second substrate 41 may have a first surface 412 and a second surface 414 opposite the first surface 412. Circuit patterns may be formed on the first surface 412 of the second substrate 41.

The second front insulating layer 42 as an insulation layer may be formed on the first surface (front surface) 412 of the second substrate 41. The second front insulating layer 42 may include a plurality of insulating layers 422 and 424. A plurality of second metal wiring layers 423 may be provided in a first passivation layer 422. In addition, the third bonding pads 43 may be provided in an outermost insulating layer of the second front insulating layer 42.

For example, the second front insulating layer 42 may surround the plurality of the second metal wiring layers 423. For example, the plurality of second metal wiring layers 423 may be a metal wiring structure including a plurality of wirings vertically stacked in the insulating layer 422. The third bonding pad 43 may be formed on an uppermost wiring among the plurality of wirings 423. For example, the wirings may include aluminum (Al), copper (Cu), tin (Sn), nickel (Ni), gold (Au), platinum (Pt), or an alloy thereof.

The third passivation layer 424 may be formed on the plurality of second metal wiring layers 423 and 423 and may expose at least a portion of the third bonding pad 43. The third passivation layer 424 may be a composite layer including a plurality of stacked insulating layers. For example, the third passivation layer 424 may include or be formed of silicon oxide, silicon nitride, or silicon carbonitride. The third passivation layer 424 may have a single-layer or multi-layer structure.

The third bonding pad 43 may be provided in the third passivation layer (also described as an insulating layer) 424. The third bonding pad 43 may be exposed through an opening of the third passivation layer 424 or beyond an outer surface of the third passivation layer 424. Although not illustrated in the figures, an additional insulation layer may be provided on the first surface 412 of the second substrate 41 to cover the circuit patterns.

The insulation layer 42 may be formed to include, for example, silicon oxide or a low dielectric material. The second metal wiring layer 423 may be electrically connected to the circuit patterns. Accordingly, the circuit pattern may be electrically connected to the third bonding pad 43 through the second metal wiring layer 423.

The second semiconductor chip 40 may be a second chiplet die (e.g., an upper chiplet die). The second semiconductor chip 40 may be a small structural unit or IP block unit of the processor chip. The first semiconductor chip 20 and the second semiconductor chip 40 may be stacked on each other to form a semiconductor device (e.g., a semiconductor processor).

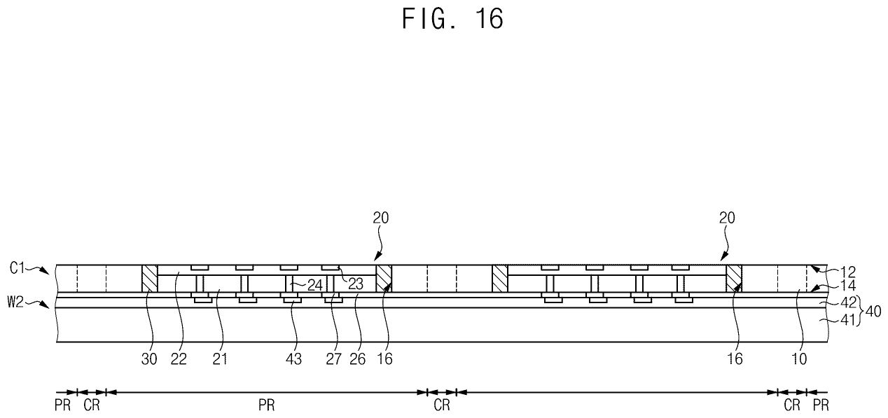

Referring to FIG. 16, a portion of the carrier substrate C1 may be partially removed until the front surface of the first semiconductor chip 20 is exposed. The removed portion may be adjacent to the first surface 12 of the carrier substrate C1.

In example embodiments, the first surface 12 of the carrier substrate C1 may be partially removed by a grinding process. The first surface 12 of the carrier substrate C1 may be removed to expose the bottom surface of the recess RC. As a result, the recess RC may become an opening 16 that penetrates entirely through the silicon substrate 10. The first substrate 21 and the first front insulating layer 22 may be disposed within the opening 16 of the silicon substrate 10. The first front insulating layer 22 of the first semiconductor chip 20 may be exposed. Accordingly, the first bonding pads 23 may be exposed from the first surface 12 of the silicon substrate 10.

Accordingly, the first semiconductor chip 20 may be disposed in the opening 16 of the silicon substrate 10, and the gap filling layer 30 may be formed to fill the gap between the outer side surface of the first semiconductor chip 20 and the sidewall of the opening 16.

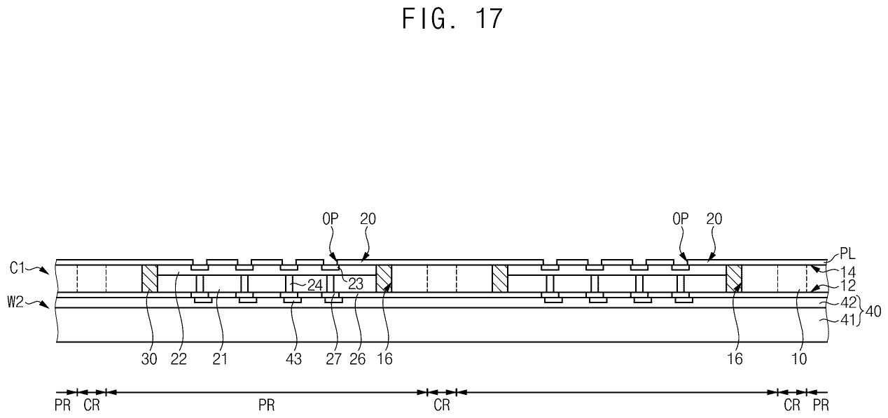

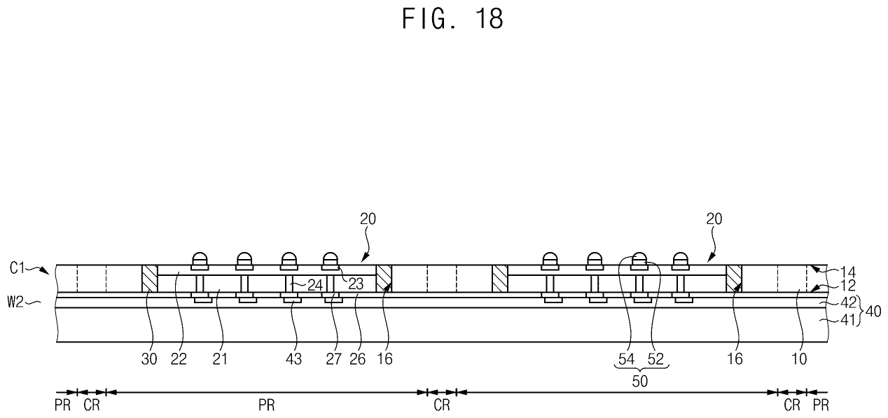

Referring to FIGS. 17 and 18, conductive bumps 50 may be formed on the first bonding pads 23 of the first semiconductor chip 20, respectively.

Though not shown in the drawings, a seed layer and a photoresist layer may be formed on the first front insulating layer 22. Subsequently an exposure process may be performed to form a photoresist pattern PL that exposes bump regions. The photoresist pattern PL may be provided with through holes OP, as illustrated in FIG. 17.

Though not shown in the drawings, after filling the openings OR of the photoresist pattern PL with a conductive material, the photoresist pattern may be removed. The conductive material may be a composite layer including a pillar bump layer and a solder bump layer.

For example, a first plating process may be performed to form a pillar bump layer on the first bonding pad 23 of the first semiconductor chip 20, and a second plating process may be performed to form a solder bump layer on the pillar bump layer. Subsequently, a reflow process may be performed to form the conductive bumps 50 including a pillar bump 52 and a solder bump 54, as shown in FIG. 18. Alternatively, the conductive bumps may be formed by one of a screen printing process, a deposition process, etc.

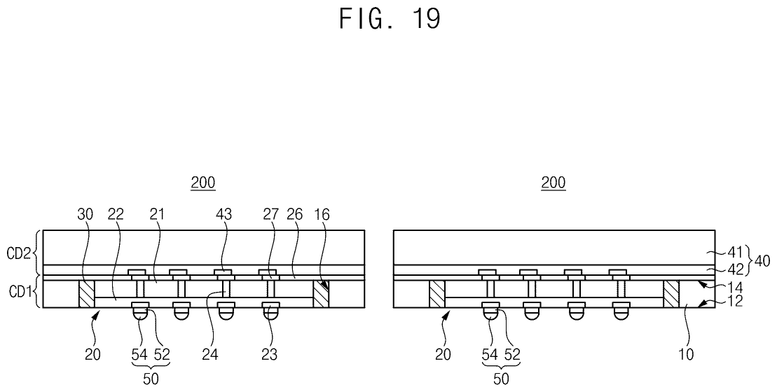

Referring to FIG. 19, the bonded structure of the carrier substrate C1 and the second wafer W2 may be cut along the cutting region CR to form a plurality of sub-packages 200 as chiplet packages. The sub-package 200 may include the first semiconductor chip (e.g., a first chiplet die) 20 and the second semiconductor chip (e.g., a second chiplet die) 40, which are bonded to each other.

Because the cutting process is performed to separate the carrier substrate C1 and the second wafer W2 at the same time, an outer side surface of the second semiconductor chip 40 and an outer side surface of the silicon substrate 10 may be positioned on the same plane. For example, an outer side surface of the second semiconductor chip 40 and an outer side surface of the silicon substrate 10 may be coplanar.

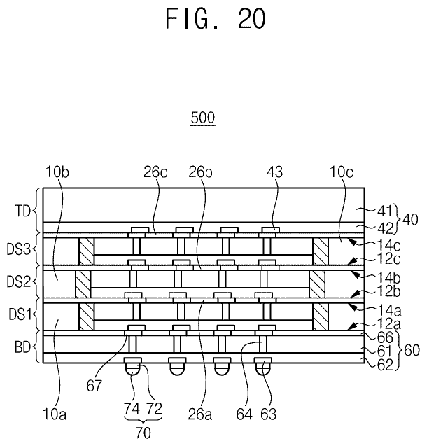

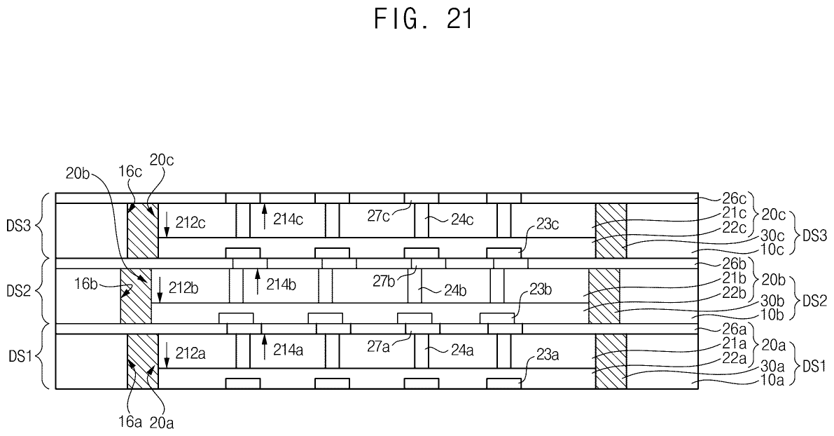

FIG. 20 is a cross-sectional view illustrating a sub-package 500 in accordance with example embodiments. FIG. 21 is a cross-sectional view illustrating an intermediate core die stack of the sub-package in FIG. 20.

The sub-package 500 may include an intermediate core die stack, a buffer die BD and a top core die TD. Except for the buffer die BD, the sub-package 500 may be substantially the same as or similar to the sub-package 200 described with reference to FIG. 1. The intermediate core die stack in FIG. 20 may have substantially the same structure of a stack of three pieces of the second die structure CD2 in FIG. 1. The top core die TD in FIG. 20 may have substantially the same structure of the first die structure CD1 in FIG. 1. Thus, same or similar reference numerals will be used to refer to the same or like elements and any further repetitive explanation concerning the same or like elements will be omitted.

Referring to FIGS. 20 and 21, a sub-package 500 may include semiconductor chips (also described as dies) stacked therein. The sub-package 500 may include a buffer die 60, and an intermediate core die stack, and a top core die TD stacked on the intermediate core die stack. The intermediate core die stack may include a plurality of die structures DS1, DS2 and DS3 sequentially stacked. Each of the die structures DS1, DS2 and DS3 may include a support substrate 10a, 10b and 10c having an opening 16a, 16b and 16c therein, a core die 20a, 20b and 20c disposed in the opening 16a, 16b and 16c, and a gap filling layer 30a, 30b and 30c that fills a gap between a sidewall of the opening and the core die 20a, 20b and 20c. For example, the core die 20a, 20b and 20c may be a semiconductor chip. The plurality of die structures DS1, DS2 and DS3 sequentially stacked. Each of the plurality of die structures DS1, DS2 and DS3 may include a corresponding one of the plurality of core dies 20a, 20b and 20c sequentially stacked on one another. The gap filling layers 30a, 30b and 30c may cover side surfaces of the plurality of core dies 20a, 20b and 20c, 20d respectively. Additionally, the sub-package 500 may further include conductive bumps 70 provided on an outer surface of the buffer die 60.

The intermediate core die stack may include a plurality of semiconductor chips (also described as dies) 20a, 20b and 20c stacked vertically. In this embodiment, the semiconductor chips 20a, 20b and 20c may be substantially the same as or similar to each other. Accordingly, same or like reference numerals will be used to refer to the same or like elements and repeated descriptions of the same elements may be omitted.

In this embodiment, the sub-package 500 as a multi-chip package is illustrated as including four semiconductor chips 20a, 20b, 20c and 40 stacked on the buffer die 60, however the invention is not limited thereto. For example, the sub-package may include 8, 12 or 16 semiconductor chips stacked on the buffer die 60.

Each of the semiconductor chips 20a, 20b and 20c and 60 may include an integrated circuit. The integrated circuit may be formed by performing wafer-level semiconductor manufacturing processes. Each semiconductor chip 20a, 20b and 20c and 60 may be, for example, a memory chip or a logic chip.

In an embodiment, the sub-package 500 may be a memory device. For example, the memory device may be a high bandwidth memory (HBM) device. Each of the semiconductor chips 40, 20a, 20b and 20c may be a semiconductor memory chip, and the buffer die 60 may be a semiconductor buffer chip having a function to control access to the semiconductor memory chips, buffer or convert signals from/into the semiconductor memory chips, or perform any other suitable functions. For example, each of the semiconductor memory chips 40, 20a, 20b and 20c may have the same storage capacity as each other.

As illustrated in FIG. 21, the intermediate core die stack may include first, second and third die structures DS1, DS2 and DS3 sequentially stacked. The first, second and third die structures DS1, DS2 and DS3 may have the same structure as each other. The first die structure DS1 may include a support substrate 10a having an opening 16a, a first core die 20a disposed in the opening 16a, and a gap filling layer 30a filling a gap between a sidewall of the opening 16a and the first core die 20a. The second die structure DS2 may include a support substrate 10b having an opening 16b, a second core die 20b disposed in the opening 16b, and a gap filling layer 30b filling a gap between a sidewall of the opening 16b and the second core die 20b. The third die structure DS3 may include a support substrate 10c having an opening 16c, a third core die 20c disposed in the opening 16c, and a gap filling layer 30c filling a gap between a sidewall of the opening 16c and the third core die 20d. The first, second, and third die structures DS1, DS2, and DS3 may be substantially the same as or similar to the first die structure CD1 of FIG. 1. Accordingly, same or like reference numerals will be used to refer to the same or like elements and repeated descriptions of the same elements may be omitted.

In example embodiments, the buffer die 60 may include a substrate 61, a front insulating layer 62, a plurality of first bonding pads 63, a plurality of through electrodes 64, and a backside insulating layer 66, and a plurality of second bonding pads 67. Additionally, the buffer die 60 may further include the conductive bumps 70 as conductive connection members provided respectively on the first bonding pads 63. The buffer die 60 may be mounted on a package substrate or an interposer via the conductive bumps 70. For example, the conductive bump 70 may include a pillar bump 72 on the first bonding pad 63 and a solder bump 74 on the pillar bump 72.

In example embodiments, the first, second and third die structures DS1, DS2 and DS3 may be sequentially stacked on the buffer die 60. The top die TD may be stacked on the third die structure DS3.

The first die structure DS1 may be bonded to a wafer including the buffer die 60 by hybrid bonding during a manufacturing process. The second bonding pad 67 of the buffer die 60 and a first bonding pad 23a of the first core die 20a may be bonded to each other by Cu—Cu bonding. A front surface of the first core die 23a (i.e., a first front insulating layer 22a on a first surface 212a of a first substrate (also described first circuit substrate) 21a) may be directly bonded to the backside insulating layer 66 of the substrate (also described circuit substrate) 61 of the buffer die 60.

The second die structure DS2 may be bonded to the first die structure DS1 by hybrid bonding. A second bonding pad 27a of the first core die 20a and a first bonding pad 23b of the second core die 20b may be bonded to each other by Cu—Cu bonding.

A first front insulating layer 22b of the second core die 20b and a first backside insulating layer 26a of the first core die 20a may be directly bonded to each other. The first backside insulating layer 26a and the first front insulating layer 22b may make contact with each other to provide a bonding structure. The first backside insulating layer 26a and the first front insulating layer 22b may include an insulating material providing excellent bonding strength. The first backside insulating layer 26a and the first front insulating layer 22b may be bonded to each other by a high-temperature annealing process while in contact with each other, thereby accomplishing covalent bonding having a relatively strong bonding strength.

Similarly, the third die structure DS3 may be bonded to the second die structure DS2 by hybrid bonding. A second bonding pad 27b of the second core die 20b and a first bonding pad 23c of the third core die 20c may be bonded to each other by Cu—Cu bonding. A first front insulating layer 22c of the third core die 20c and a first backside insulating layer 26b of the second core die 20b may be directly bonded to each other.

The top die TD may be bonded to the third die structure DS3 by hybrid bonding. A second front insulating layer 42 of the top die TD and the first backside insulating layer 26c of the third core die 20c may be directly bonded to each other. A second bonding pad 27c of the third core die 20c and a third bonding pad 43 of the top die TD may be bonded to each other by Cu—Cu bonding (e.g., pad to pad direct bonding).

Hereinafter, a method of manufacturing the sub-package of FIG. 20 will be described.

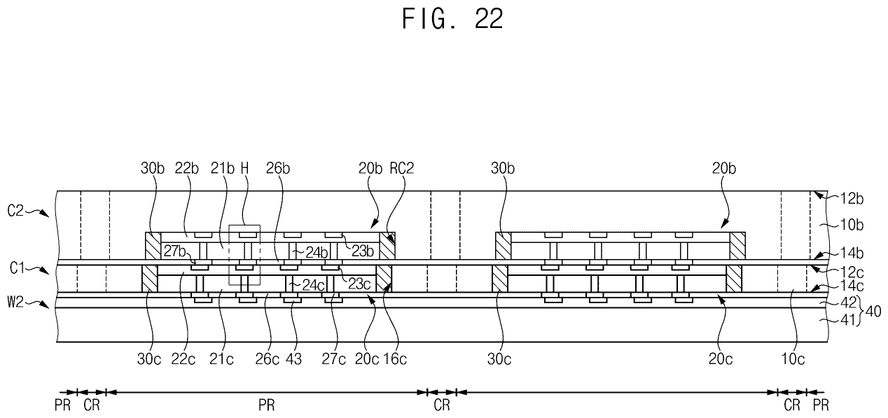

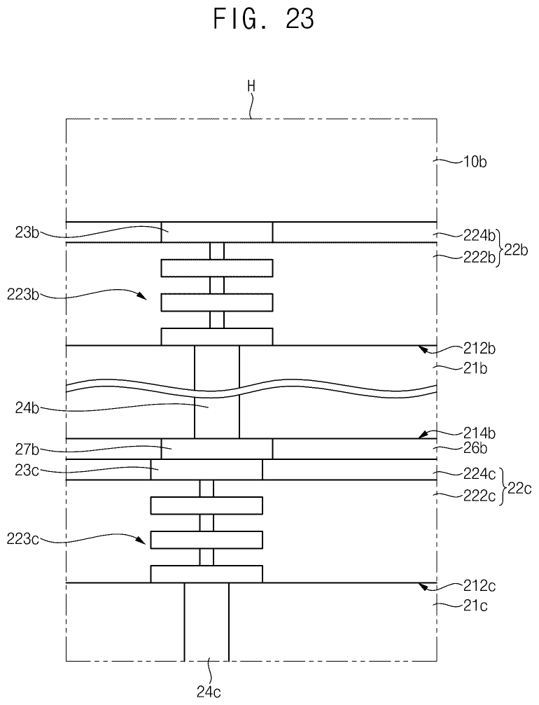

FIGS. 22 to 28 are cross-sectional views illustrating a method of manufacturing a sub-package in accordance with example embodiments. FIG. 23 is an enlarged cross-sectional view illustrating portion ‘H’ in FIG. 22.

Referring to FIGS. 22 and 23, processes the same as or similar to the processes described with reference to FIGS. 4 to 16 may be performed thereby attaching a first carrier substrate C1 including third core dies 20c formed therein to a second wafer W2 including top core dies 40 formed therein. Subsequently, processes the same as or similar to the processes described with reference to FIGS. 4 to 13 may be performed, thereby forming a second carrier substrate C2 including second core dies 20b formed therein, and the second carrier substrate C2 may be attached to a first carrier substrate C1 by wafer-to-wafer hybrid bonding process. In example embodiments, in view of the manufacturing process, the first semiconductor chip 20 and the second semiconductor chip 40 of FIG. 16 may correspond to the third core die 20c and the top core die 40 of FIG. 22, respectively. By the bonding, a backside surface of the second core die 20b of the second carrier substrate C2 may face a front surface of the third core die 20c of the first carrier substrate C1.

When the second carrier substrate C2 and the first carrier substrate C1 are bonded to each other by wafer-to-wafer bonding (e.g., by a thermal compression process), the second core die 20b of the second carrier substrate C2 and the third core die 20c of the first carrier substrate C1 may be bonded to each other in a manner of hybrid bonding. For example, as illustrated in FIG. 23, the bonding pad 27b of the second core die 20b and the bonding pad 23c of the third core die 20c may be directly bonded to each other by Cu—Cu bonding. Additionally, the front surface of the third core die 20c (i.e., a first front insulating layer 22a on a first surface 212a of a first substrate (also described circuit substrate) 21c) may be directly bonded to the backside surface of the second core die 20b (i.e., a backside insulating layer 26b on a second surface 214b of a first substrate (also described first circuit substrate) 21b).

When the second carrier substrate C2 and the first carrier substrate C1 are bonded to each other by wafer-to-wafer bonding, no step difference may be generated between the backside surface of the first substrate 21b of the second core die 20b and an upper surface of a gap filling layer 30b. Accordingly, it may be possible to prevent voids from occurring between the first backside insulating layer 26b of the second core die 20b and the first front insulating layer 22c of the third core die 20c. For example, when the second carrier substrate C2 and the first carrier substrate C1 are bonded to each other by wafer-to-wafer bonding, no bevel step difference is generated between a second surface 14b of a silicon substrate 10b and a backside surface of the first substrate 21b of the second core die 20b at an edge region of the second carrier substrate C2. Accordingly, it may be possible to prevent a void from occurring between the edge region of the second carrier substrate C2 and an edge region of the first carrier substrate C1.

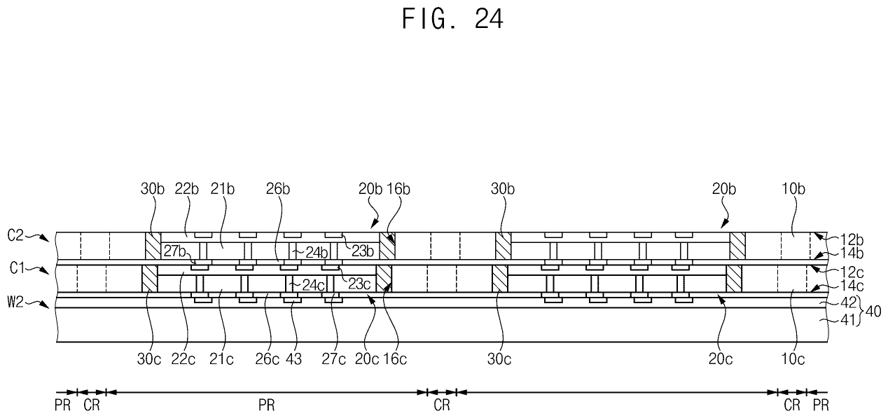

Referring to FIG. 24, a first surface 12b of the second carrier substrate C1 may be partially removed until a front surface of the second core die 20b is exposed.

In example embodiments, the first surface 12b of the second carrier substrate C2 may be partially removed by a grinding process. The first surface 12b of the second carrier substrate C2 may be removed to expose a bottom surface of a recess RC2. Accordingly, the recess RC2 may become an opening 16b that penetrates the silicon substrate 10b. The first substrate 21b and the first front insulating layer 22b may be disposed within the opening 16b of the silicon substrate 10b. The first front insulating layer 22b of the second core die 20b may be exposed by the opening 16b. Accordingly, the first bonding pads 23b may be exposed from the first surface 12b of the silicon substrate 10b.

The second core die 20b may be disposed in the opening 16b of the silicon substrate 10b, and the gap filling layer 30b may be formed to fill a gap between an outer side surface of the second core die 20b and a sidewall the opening 16b.

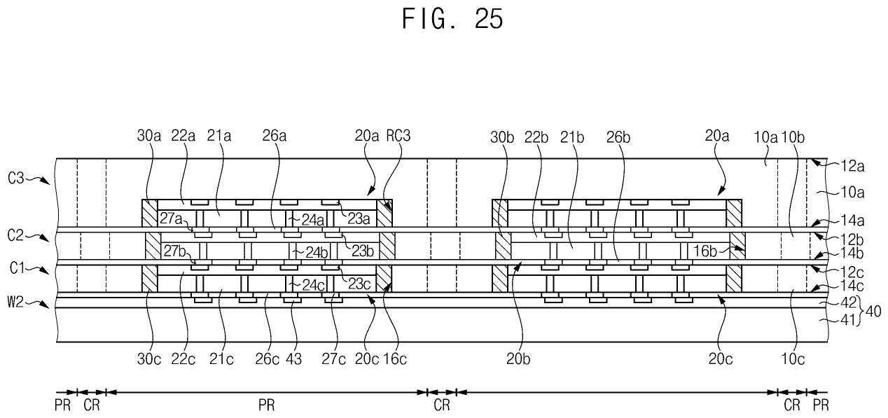

Referring to FIG. 25, processes the same as or similar to the processes described with reference to FIGS. 4 to 13 may be performed to form a third carrier substrate C3 including first core dies 20a formed therein, and the third carrier substrate C3 may be attached to the second carrier substrate C2 by wafer-to-wafer hybrid bonding process. In example embodiments, by the bonding, a backside surface of the first core die 20a of the third carrier substrate C3 may face a front surface of the second core die 20b of the second carrier substrate C2.

When the third carrier substrate C3 and the second carrier substrate C2 are bonded to each other by wafer-to-wafer bonding (e.g., by a thermal compression process), the first core die 20a of the third carrier substrate C3 and the second core die 20b of the second carrier substrate C2 may be bonded to each other in a manner of hybrid bonding. For example, the bonding pad 27a of the first core die 20a and the bonding pad 23b of the second core die 20b may be directly bonded to each other by Cu—Cu bonding. Additionally, the front surface of the second core die 20b (i.e., a first front insulating layer 22b on a first surface 212b of a first substrate 21b) may be directly bonded to the backside surface of the first core die 20a (i.e., a backside insulating layer 26a on a second surface 214a of a first substrate 21a).

When the third carrier substrate C3 and the second carrier substrate C2 are bonded to each other by wafer-to-wafer bonding, no step difference is generated between the backside surface of the first substrate 21a of the first core die 20a and an upper surface of a gap filling layer 30a. Accordingly, it may be possible to prevent voids from occurring between the first backside insulating layer 26a of the first core die 20a and the first front insulating layer 22b of the second core die 20b. For example, when the third carrier substrate C3 and the second carrier substrate C2 are bonded to each other by wafer-to-wafer bonding, no bevel step difference is generated between a second surface 14a of a silicon substrate 10a and a backside surface of the first substrate 21a of the first core die 20a at an edge region of the third carrier substrate C3. Accordingly, it may be possible to prevent a void from occurring between the edge region of the third carrier substrate C3 and an edge region of the second carrier substrate C2.

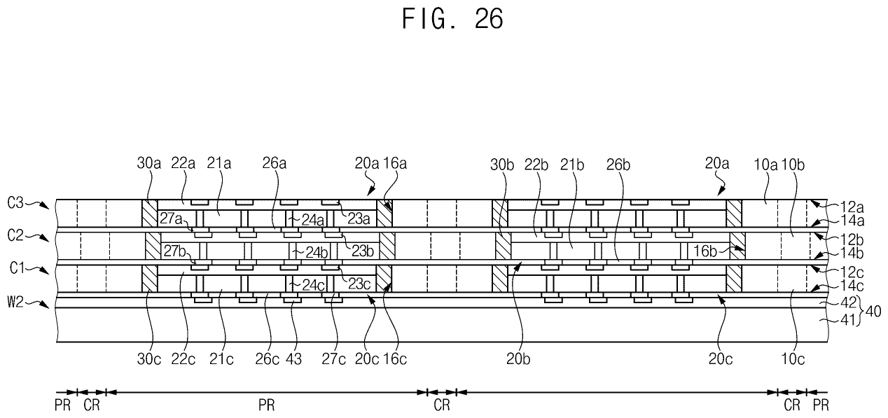

Referring to FIG. 26, a first surface 12a of the third carrier substrate C2 may be partially removed until a front surface of the first core die 20a is exposed.

In example embodiments, the first surface 12a of the third carrier substrate C3 may be partially removed by a grinding process. The first surface 12a of the third carrier substrate C3 may be removed to expose a bottom surface of a recess RC3. Accordingly, the recess RC3 may become an opening 16a that penetrates the silicon substrate 10a. The first substrate 21a and the first front insulating layer 22a may be disposed within the opening 16a of the silicon substrate 10a. The first front insulating layer 22a of the first core die 20a may be exposed by the opening 16a. Accordingly, the first bonding pads 23a may be exposed from the first surface 12a of the silicon substrate 10a.

The first core die 20a may be disposed in the opening 16a of the silicon substrate 10a, and the gap filling layer 30a may be formed to fill a gap between an outer side surface of the first core die 20a and a sidewall of the opening 16a.

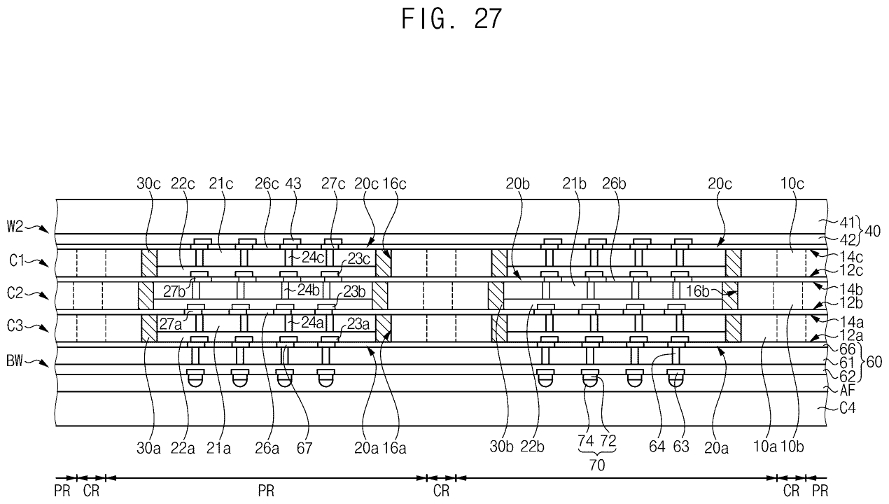

Referring to FIG. 27, the first, second and third carrier substrate C1, C2 and C3 of FIG. 26 (in which the first, second and third core dies 20a, 20b and 20c are stacked) may be attached on a buffer wafer BW (in which a buffer die 60 is formed) by wafer-to-wafer hybrid bonding process.

In example embodiments, the structure of FIG. 26 may be turned over, and the third carrier substrate C3 may be bonded on the buffer wafer BW including the buffer dies 60. A front surface of the first core die 20a may face a backside surface of the buffer die 60 of the buffer wafer BW by the bonding.

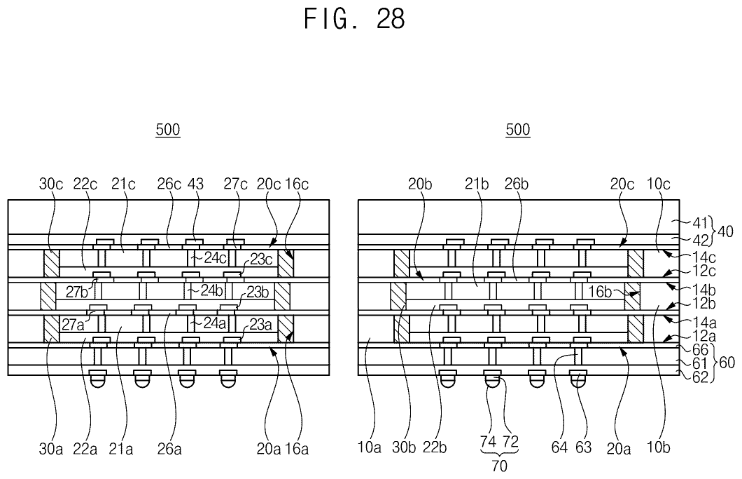

When the third carrier substrate C3 and the buffer wafer BW are bonded to each other by wafer-to-wafer bonding (e.g., by a thermal compression process), the first core die 20a of the third carrier substrate C3 and the buffer die 60 of the buffer wafer BW and may be bonded to each other in a manner of hybrid bonding. For example, the bonding pad 23a of the first core die 20a and the second bonding pad 67 of the buffer die 60 may be directly bonded to each other by Cu—Cu bonding. Additionally, the backside surface of the buffer die 60 (i.e., a backside insulating layer 66 on a backside surface of a substrate 61) may be directly bonded to the front surface of the first core die 20a (i.e., the first front insulating layer 22a on a first surface 212a of the first substrate 21a). The first bonding pad 23a of the first core die 20a and the second bonding pad 17 of the buffer die 60 may be bonded to each other by Cu—Cu bonding (e.g., pad to pad direct bonding). Referring to FIG. 28, the buffer wafer BW, the first to third carrier substrates C1, C2, C3 and the second wafer W2 may be cut along a cutting region CR to form a plurality of sub-packages 500 of FIG. 20.

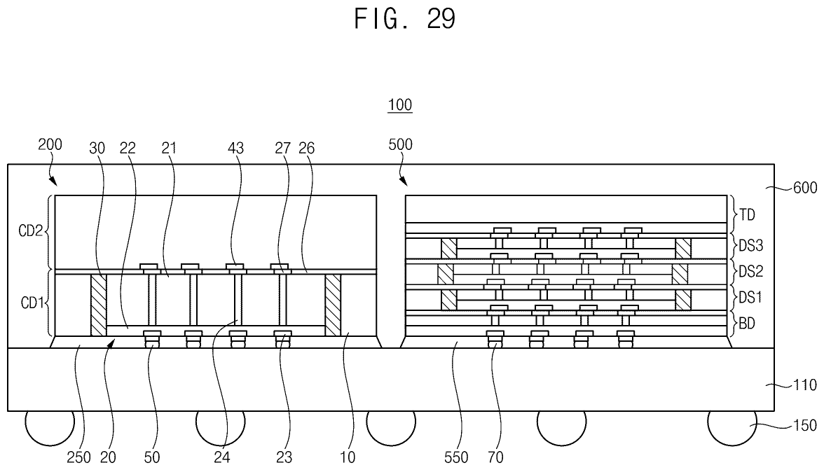

FIG. 29 is a cross-sectional view illustrating a semiconductor package in accordance with example embodiments. The semiconductor package includes the sub-package illustrated in FIGS. 1 and 20, however the present inventive concept is not limited thereto.

Referring to FIG. 29, a semiconductor package 100 may include a package substrate 110, a first sub-package 200, and a second sub-package 500. Additionally, the semiconductor package 100 may further include first and second underfill members 250 and 550 and a sealing member 600. The first sub-package 200 may be substantially the same as or similar to the sub-package described with reference to FIG. 1. The second sub-package 500 may be substantially the same as or similar to the sub-package described with reference to FIG. 20. Thus, same reference numerals will be used to refer to the same or like elements and any further repetitive explanation concerning the same or like elements will be omitted.

In example embodiments, the semiconductor package 100 may be provided as a portion of a memory module having a 2.5 D package structure. In this case, the package substrate 110 may be or include an interposer for electrically connecting the first and second sub-packages 200 and 500 to each other.

In example embodiments, the first sub-package 200 may be or include a logic device, and the second sub-package 500 may be or include a memory device. The logic device may be an application specific integrated circuit (ASIC) chip including, at least one of a graphics processing unit (GPU), a central processing unit (CPU), a microprocessor, a microcontroller, an application processor (AP), a digital signal processing core (digital signal processing core), etc. The memory device may include, for example, DRAM, SRAM, flash, PRAM, ReRAM, FeRAM, or MRAM. The memory device may be a HBM device.

In example embodiments, the package substrate 110 may have an upper surface and a lower surface opposite to the upper surface, and may be, for example, a printed circuit board (PCB), a silicon interposer, or a redistribution interposer. The printed circuit board may be a multilayer circuit board having various circuit patterns therein.

The first sub-package 200 may be mounted on the package substrate 110. The first sub-package 200 may be mounted on an upper surface of the package substrate 110 using a flip chip bonding method. The first sub-package 200 may be arranged such that a first front insulating layer 22 faces the package substrate 110. The first bonding pads 23 of the first sub-package 200 may be electrically connected to substrate pads of the package substrate 110 through conductive bumps 50.

The second sub-package 500 may be horizontally spaced apart from the first sub-package 200 on the package substrate 110. The second sub-package 500 may be mounted on the upper surface of the package substrate 110 via conductive bumps 70.

The first sub-package 200 and the second sub-package 500 may be electrically connected to each other through wires inside the package substrate 110. The package substrate 110 may provide high-density interconnection between the first and second sub-packages 200 and 500.

In example embodiments, the first and second underfill members 250 and 550 may include a material with relatively high fluidity to effectively fill small spaces between the first and second sub-packages 200 and 500 and the package substrate 110. For example, the first and second underfill members 250 and 550 may include an adhesive containing an epoxy material.

The sealing member 600 may be provided on the upper surface of the package substrate 110 to cover the first and second sub-packages 200 and 500. For example, the sealing member 600 may include an epoxy mold compound (EMC). The sealing member 600 may include UV resin, polyurethane resin, silicone resin, silica fillers, etc.

Although not illustrated in the figures, a heat slug may cover and be in thermal contact with the first and second sub-packages 200 and 500 on the package substrate 110. In this case, the sealing member 600 may be omitted. Alternatively, the sealing member 600 may expose upper surfaces of the first and second sub-packages 200 and 500, and a heat dissipation member may be disposed on the upper surfaces of the first and second sub-packages 200 and 500 exposed by the sealing member 600. The heat dissipation member may include, for example, a thermal interface material (TIM). The heat slug may be in thermal contact with the first and second sub-packages 200 and 500 via the heat dissipation member.

The semiconductor package 100 may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a first die structure including a support substrate having an opening therein, a first semiconductor chip disposed in the opening, and a gap filling layer filling a gap between a sidewall of the opening and the first semiconductor chip; and
a second die structure stacked on the first die structure, the second die structure including a second semiconductor chip electrically connected to the first semiconductor chip,
wherein the first semiconductor chip includes a first circuit substrate, a first front insulating layer formed on a first surface of the first circuit substrate and provided with first bonding pads, and a first backside insulating layer formed on a second surface of the first circuit substrate and provided with second bonding pads, and the second surface of the first circuit substrate is positioned opposite to the first surface of the first circuit substrate,
wherein the second semiconductor chip includes a second circuit substrate, and a second front insulating layer formed on a first surface of the second circuit substrate and provided with third bonding pads, and
wherein the second bonding pads are directly bonded to the third bonding pads respectively.

2. The semiconductor package of claim 1, wherein the first backside insulating layer is directly bonded to the second front insulating layer.

3. The semiconductor package of claim 1, wherein the support substrate is a silicon substrate.

4. The semiconductor package of claim 1, wherein the gap filling layer is formed of silicon oxide.

5. The semiconductor package of claim 1, wherein the first backside insulating layer laterally extends along the second surface of the first circuit substrate to cover the gap filling layer.

6. The semiconductor package of claim 1, wherein an outer side surface of the second semiconductor chip and an outer side surface of the support substrate are coplanar.

7. The semiconductor package of claim 1, wherein the second surface of the first circuit substrate of the first semiconductor chip and an upper surface of the gap filling layer are positioned on the same plane.

8. The semiconductor package of claim 1, wherein the second surface of the first circuit substrate of the first semiconductor chip and an upper surface of the support substrate are positioned on the same plane.

9. The semiconductor package of claim 1, wherein the support substrate has a first coefficient of thermal expansion, and the gap filling layer has a second coefficient of thermal expansion that is greater than the first coefficient of thermal expansion.

10. The semiconductor package of claim 1, further comprising:
conductive bumps provided on the first bonding pads, respectively.

11. A semiconductor package, comprising:
a first die structure including:
a support substrate having a first surface and a second surface opposite to the first surface and having an opening that extends from the first surface to the second surface;
a first semiconductor chip disposed in the opening; and
a gap filling layer that fills a gap between a sidewall of the opening and the first semiconductor chip; and
a second die structure stacked on the first die structure, the second die structure including a second semiconductor chip that is electrically connected to the first semiconductor chip,
wherein an outer side surface of the support substrate and an outer side surface of the second semiconductor chip are positioned on the same plane.

12. The semiconductor package of claim 11,
wherein the first semiconductor chip includes:
a first circuit substrate,
a plurality of through electrodes penetrating the first circuit substrate,
first bonding pads provided on the first surface of the first circuit substrate and electrically connected to the plurality of through electrodes, and
second bonding pads provided on a second surface of the first circuit substrate opposite to the first surface and electrically connected to the plurality of through electrodes,
wherein the second semiconductor chip includes a second circuit substrate and third bonding pads provided on a first surface of the second circuit substrate, and wherein the first bonding pads are directly bonded to the second bonding pads.

13. The semiconductor package of claim 12, wherein the first semiconductor chip further includes a first backside insulating layer provided on the second surface of the first circuit substrate and exposing at least portions of the second bonding pads,
wherein the second semiconductor chip further includes a second front insulating layer provided on the first surface of the second circuit substrate and exposing at least portion of each of the third bonding pads, and
wherein the first backside insulating layer is directly bonded to the second front insulating layer.

14. The semiconductor package of claim 13, wherein the first backside insulating layer laterally extends along the second surface of the first circuit substrate to cover the gap filling layer.

15. The semiconductor package of claim 13, wherein the second surface of the first circuit substrate of the first semiconductor chip and an upper surface of the gap filling layer are positioned on the same plane.

16. The semiconductor package of claim 12, wherein the second surface of the first circuit substrate of the first semiconductor chip and an upper surface of the support substrate are positioned on the same plane.

17. The semiconductor package of claim 11, wherein, the support substrate is a silicon substrate.

18. The semiconductor package of claim 11, wherein the gap filling layer is formed of silicon oxide.

19. A semiconductor package, comprising:
a first semiconductor chip;
a plurality of die structures sequentially stacked on the first semiconductor chip; and
a second semiconductor chip stacked on an uppermost die structure of the plurality of die structures,
wherein each of the plurality of die structures includes:
a support substrate having an opening therein,
a third semiconductor chip disposed in the opening, and
a gap filling layer that fills a gap between a sidewall of the opening and the third semiconductor chip, and
wherein an outer side surface of the support substrate of the uppermost die structure and an outer side surface of the second semiconductor chip are positioned on the same plane.

20. The semiconductor package of claim 21, wherein the first semiconductor chip is a semiconductor buffer chip, and the second and third semiconductor chips are semiconductor memory chips.
